(19) United States
(12) Patent Application Publication
(10) Pub. No.: US 2014/0137794 A1
(43) Pub. Date: May 22, 2014

(54) Method of Preparing A Directional Solidification System Furnace

(71) Applicant: MEMC SINGAPORE, PTE. LTD (UEN200614797D, Singapore (SG)

(72) Inventors: Dale A. Witte, Wentzville, MO (US); Jihong John Chen, St. Charles, MO (US); Travis Hambach, Warrenton, MO (US); Linda Swiney, St. Charles, MO (US)

(73) Assignee: MEMC SINGAPORE, PTE. LTD (UEN200614797D), Singapore (SG)

(21) Appl. No.: 13/680,892

(22) Filed: Nov. 19, 2012

(51) Int. Cl. C30B 11/14

(52) U.S. Cl. CPC C30B 11/14
USPC 117/58

(57) ABSTRACT

A method of preparing a directional solidification system (DSS) furnace for use in semiconductor or solar manufacturing includes slicing a plurality of cylindrical rods to produce a plurality of rectangular seed bricks, a plurality of corner portions, and a plurality of quarter sections, and cropping the plurality of rectangular seed bricks into a plurality of rectangular seeds.

### FIELD

This disclosure generally relates to seed bricks for use in manufacturing semiconductor or solar wafers, and more specifically, to producing seed bricks.

### BACKGROUND

Silicon seed bricks are the starting material in many processes for fabricating semiconductor electronic components and solar materials. For example, a silicon seed brick may be split into multiple seed crystals. To produce semiconductor or solar wafers, and in particular high efficiency solar wafers, a silicon ingot may be produced by melting polycrystalline silicon in a crucible of a directional solidification system (DSS) furnace from the top down to the seeds at the bottom of the crucible. Directional solidification generally maintains the seed crystalline structure throughout the produced ingot. The silicon ingot is then machined into wafers, which can be used in a variety of electronic or solar components.

In some applications, cutting individual seed bricks from a cylindrical rod may be time-consuming. Further, using a band saw to cut seed bricks may result in a poor surface finish on the resulting seed bricks, and may cause irregular and/or misshapen mating surfaces on the resulting seed bricks.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect is a method of preparing a directional solidification system (DSS) furnace for use in semiconductor or solar manufacturing. The method includes slicing a plurality of cylindrical rods to produce a plurality of rectangular seed bricks, a plurality of corner portions, and a plurality of quarter sections, and cropping the plurality of rectangular seed bricks into a plurality of rectangular seeds. The method further includes arranging the plurality of rectangular seeds in a crucible of the DSS furnace, and surrounding the arranged seeds with at least a portion of the plurality of corner portions and the plurality of quarter sections.

Another aspect is a method of preparing a directional solidification system (DSS) furnace for use in semiconductor or solar manufacturing. The method includes slicing a plurality of cylindrical rods by connecting an alignment layer to a top surface of a template, the template including a grid of horizontal and vertical slots, and slicing through the plurality of rods and the alignment layer to produce a plurality of rectangular seed bricks, a plurality of corner portions, and a plurality of quarter sections. The method further includes cropping the plurality of rectangular seed bricks into a plurality of rectangular seeds, arranging the plurality of rectangular seeds in a crucible of the DSS furnace, and surrounding the arranged seeds with at least a portion of the plurality of corner portions and the plurality of quarter sections.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a flowchart of a method for use in producing a plurality of seed bricks.

FIG. 2 is a perspective view of an apparatus of one embodiment for producing seed bricks.

FIG. 3 is a perspective view of the apparatus shown in FIG. 2 including an alignment layer.

FIG. 4 is a perspective view of the apparatus shown in FIG. 3 including alignment lines drawn on the alignment layer.

FIG. 5 is a schematic diagram of the apparatus shown in FIG. 4 including diagonal alignment lines.

FIG. 6 is a perspective view of the apparatus shown in FIG. 5 including a plurality of cylindrical rods.

FIG. 7 is a schematic diagram of the apparatus shown in FIG. 6.

FIG. 8 is a schematic diagram of the apparatus shown in FIG. 6.

FIG. 9 is a perspective view of a sliced cylindrical rod produced using the apparatus shown in FIG. 6.

FIG. 10 is a perspective view of a seed brick taken from the sliced cylindrical rod shown in FIG. 9.

FIG. 11 is a perspective view of a pre-melt arrangement including seeds produced using the method shown in FIG. 1.

FIG. 12 is a perspective view of an alternative pre-melt arrangement including seeds produced using the method shown in FIG. 1.

Like reference symbols in the various drawings indicate like elements.

### DETAILED DESCRIPTION

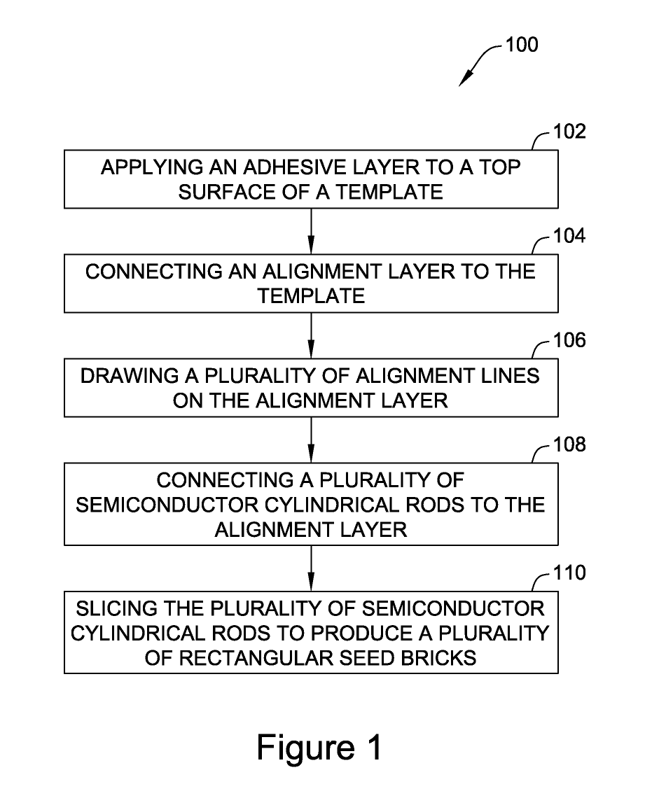

Referring initially to FIG. 1, a method for producing seed bricks is indicated generally at 100. Seed bricks produced using method 100 may be used to produce semiconductor or solar wafers, including high-efficiency solar wafers, as described herein.

The method 100 generally includes a step 102 of applying an adhesive layer to a top surface of a template, a step 104 of connecting an alignment layer to the template, a step 106 of drawing a plurality of alignment lines on the alignment layer, a step 108 of connecting a plurality of cylindrical rods to the alignment layer, and a step 110 of slicing the plurality of cylindrical rods to produce a plurality of rectangular seed bricks.

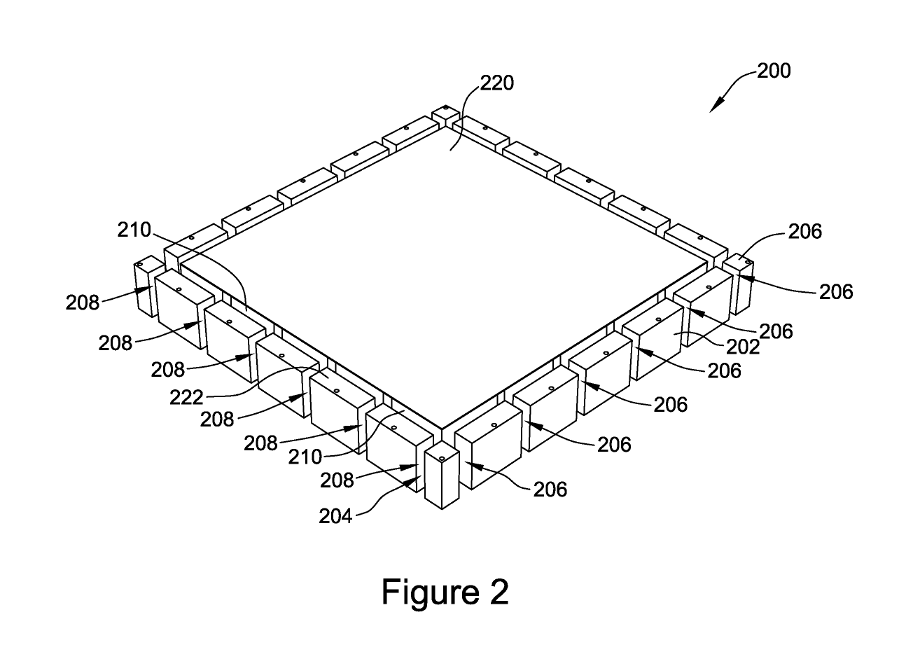

Referring to FIGS. 2-8, an apparatus for producing seed bricks is indicated generally at 200. As shown in FIG. 2, apparatus 200 includes a template 202 that includes a plurality of slots 204 defined therethrough. Slots 204 include vertical slots 206 and horizontal slots 208 that are orthogonal to vertical slots 206.

In this embodiment, template 202 includes six vertical slots 206 and six horizontal slots 208 arranged in a grid that subdivides template 202 into twenty-five square-shaped sections 210 of equal size. In this embodiment, each square-shaped section 210 has dimensions of approximately 156 millimeters (mm) by approximately 156 mm. As template 202 includes a 5×5 grid of square-shaped sections 210, template 202 may also be referred to as a G5 template.

In other embodiments, template 202 may include any suitable number of horizontal and vertical slots 206 and 208, so as to divide template 202 into any suitable number of square-shaped sections 210. For example, in some embodiments, template 202 includes nine vertical slots 206 and nine horizontal slots 208 to divide template 202 into sixty four square-shaped sections 210 (i.e., an 8×8 grid).

As shown in FIG. 2, an adhesive layer 220 is applied to a top surface 222 of template 202. In this embodiment, adhesive layer 220 is a layer of double-sided mounting tape that covers the twenty-five square-shaped sections 210. In other embodiments, adhesive layer 220 may be any suitable adhesive and have any suitable dimensions.

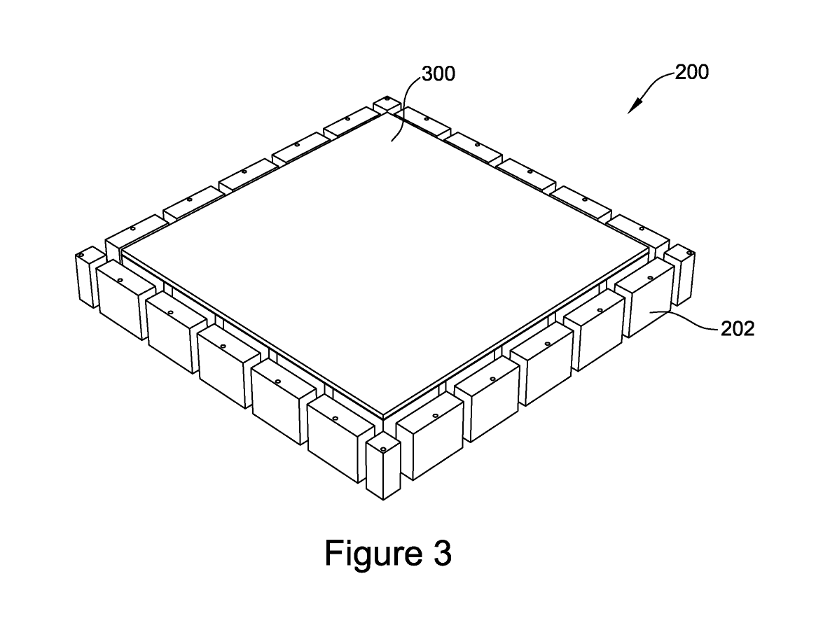

Referring back to FIG. 1, an alignment layer is connected in step 104 to the template. FIG. 3 shows an alignment layer 300 connected to template 202. Specifically, adhesive layer 220 facilitates connecting alignment layer 300 to template 202. In this embodiment, similar to adhesive layer 220, alignment layer 300 covers the twenty-five square-shaped sections 210 of template 200.

Referring back to FIG. 1, a plurality of alignment lines are drawn in step 106 on the alignment layer. The alignment lines may suitably be drawn using a suitable writing instrument, such as a pen, pencil, marker, etc., and may be drawn with the aid of a straight edge.

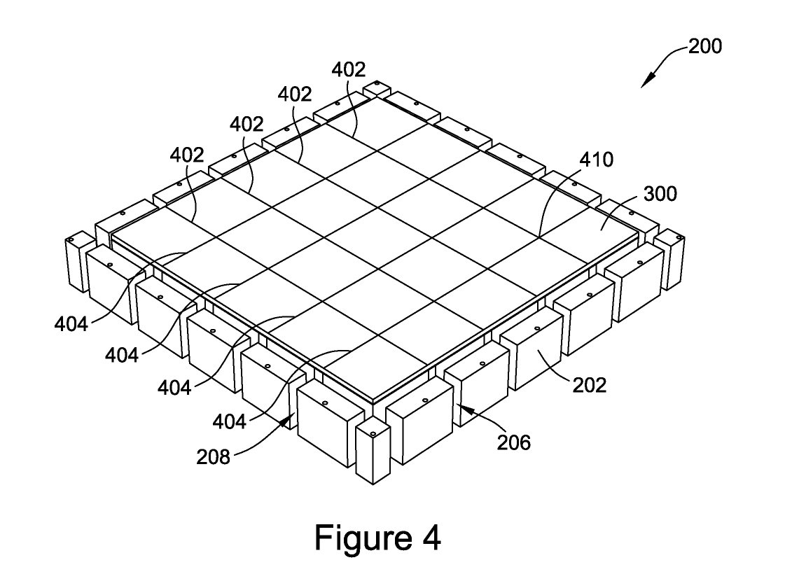

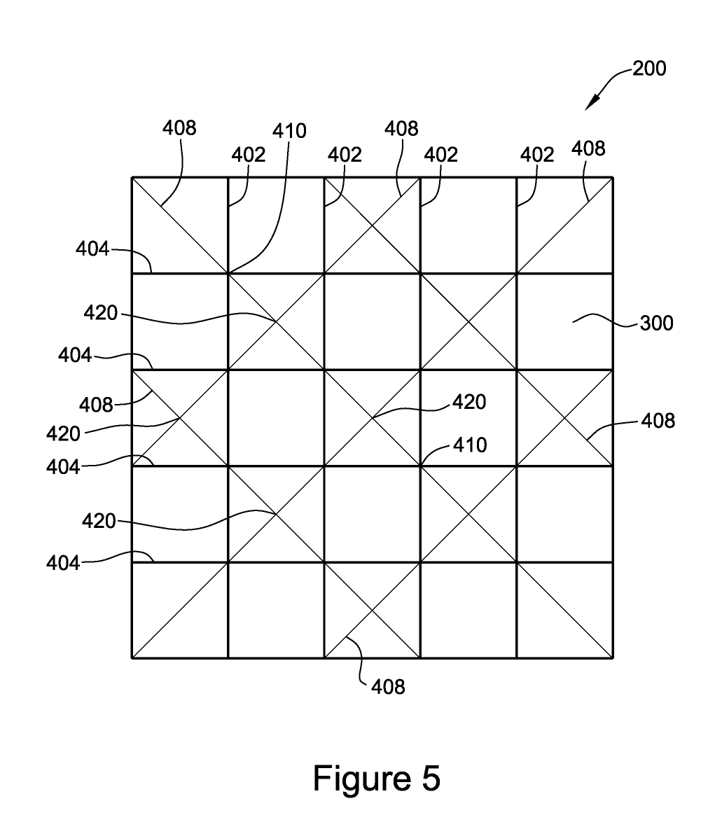

FIG. 4 shows vertical alignment lines 402 and horizontal alignment lines 404 drawn on alignment layer 300. In this embodiment, alignment layer 300 is a foam layer. In other embodiments, alignment layer 300 may be any suitable material. Vertical and horizontal alignment lines 402 and 404 are substantially aligned with vertical and horizontal slots 206 and 208 of template 202. Once vertical and horizontal alignment lines 402 and 404 are drawn, diagonal alignment lines 408 can be drawn, as shown in FIG. 5. Diagonal alignment lines 408 pass through intersections 410 between vertical and horizontal alignment lines 402 and 404.

An intersection between diagonal alignment lines 408 is referred to as a node 420. In this embodiment, diagonal alignment lines 408 intersect to demarcate a plurality of nodes 420 on alignment layer 300.

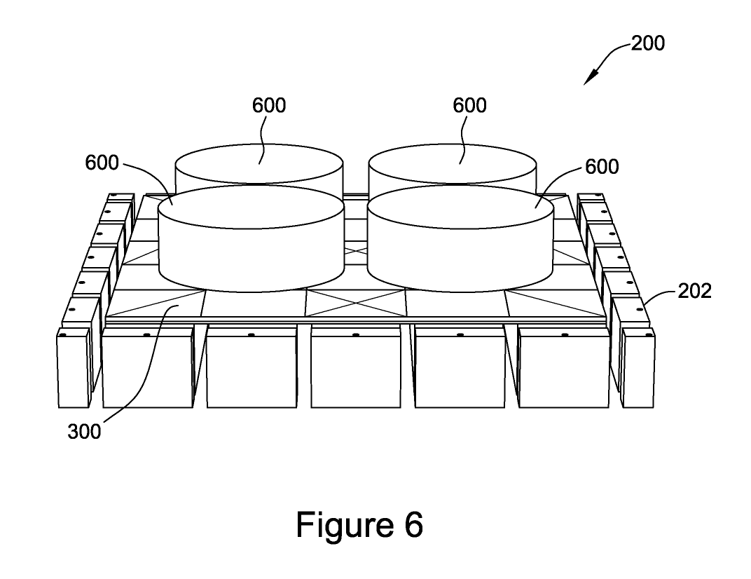

Referring back to FIG. 1, cylindrical rods are connected in step 108 to the alignment layer. The cylindrical rods are made of a semiconductor or solar material. In this embodiment, cylindrical rods are made of monocrystalline silicon. FIG. 6 shows four cylindrical rods 600 connected to alignment layer 300, though other numbers of rods may be used. In this embodiment, each cylindrical rod 600 is substantially cylindrical with a diameter of approximately 300 mm and a height of approximately 312 mm or approximately 468 mm. In other embodiments, cylindrical rods 600 may have any suitable dimensions. For example, in some embodiments, each cylindrical rod has a diameter greater than 220 mm.

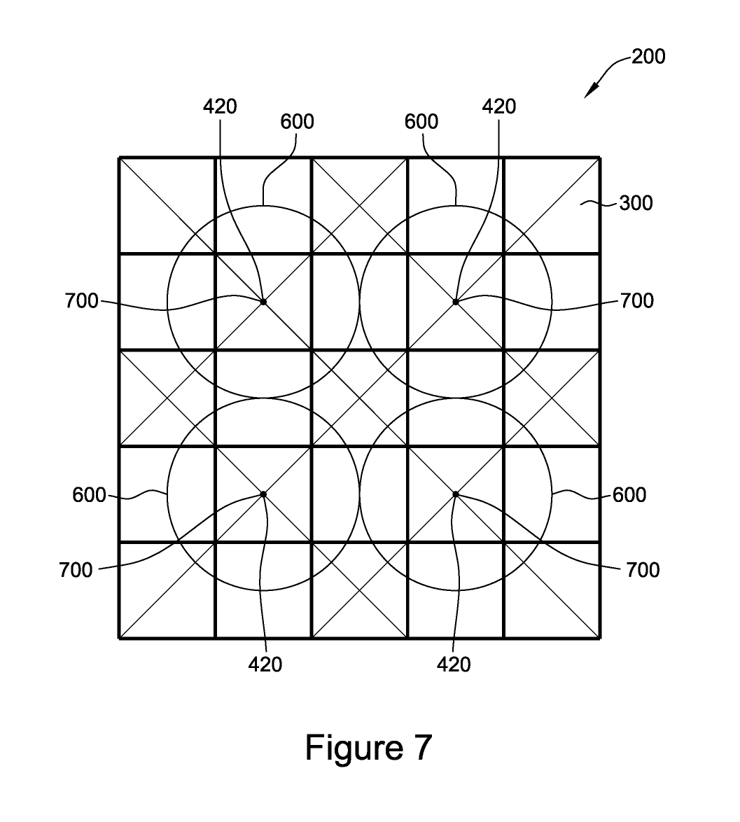

As shown in FIG. 7, cylindrical rods 600 are connected to alignment layer 300 such that a center 700 of each cylindrical rod 600 is aligned with a respective node 420, and zero dislocation (“ZD”) lines of each cylindrical rod 600 are aligned with diagonal alignment lines 408. In this embodiment, where template 202 is a 5×5 template, four cylindrical rods 600 are connected to alignment layer 300. In other embodiments, a different number of cylindrical rods 600 may be connected to alignment layer 300, depending on the size of template 202. For example, in an embodiment using an 8×8 template 202, up to sixteen cylindrical rods 600 may be connected to alignment layer 300.

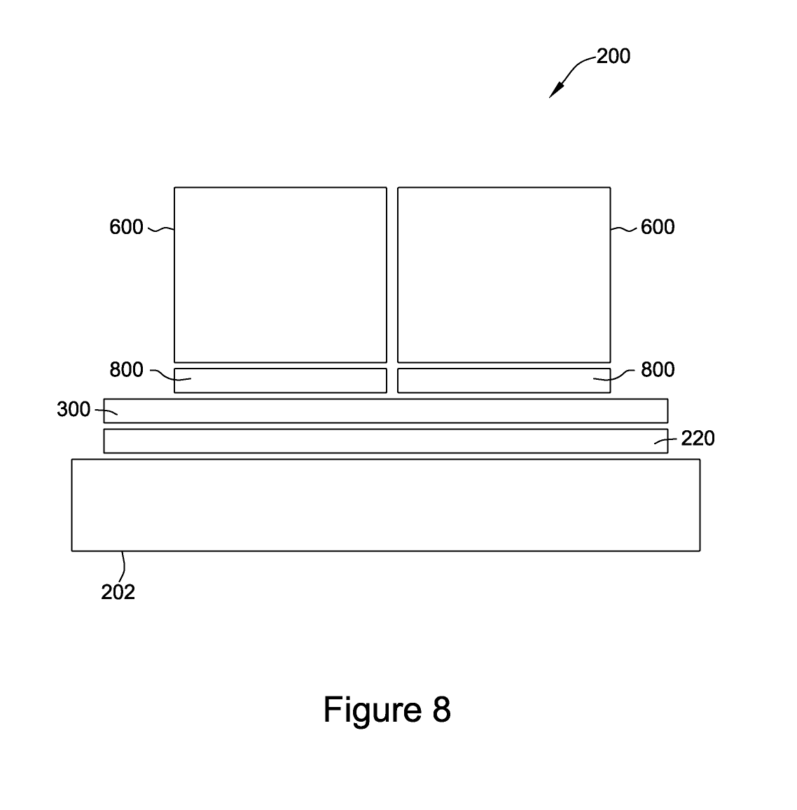

As shown in FIG. 8, in this embodiment, each cylindrical rod 600 is connected to alignment layer 300 using double-sided mounting tape 800. More specifically, double-sided mounting tape 800 is a circular piece of tape with approximately the same diameter as cylindrical rod 600.

In this embodiment, the following process is performed to connect each cylindrical rod 600 to alignment layer 300. First, cylindrical rod 600 is placed onto alignment layer 300 without using double-sided mounting tape 800. Cylindrical rod 600 is positioned until the center 700 of cylindrical rod 600 is aligned with an associated node 420. Once cylindrical rod 600 is aligned, at least one or more alignment marks are made on a side of cylindrical rod 600 that corresponds to a crystal 1-1-0 direction. This mark may be a semi-notch, ZD growth line, or other mark that is in the crystal 1-1-0 direction. For example, one or more alignment marks may be drawn on the side of cylindrical rod 600 where diagonal alignment lines 408 intersect cylindrical rod 600. One or more alignment marks may also be drawn on alignment layer 300. Also, other crystal directions may be used in other embodiments.

Cylindrical rod 600 is then removed from alignment layer 300. In this embodiment, double-sided mounting tape 800 includes opposing adhesive surfaces that are each covered by a removable non-stick protective film. One non-stick protective film is peeled away to expose one of the two adhesive surfaces, and double-sided mounting tape 800 is adhered to cylindrical rod 600 using the exposed adhesive surface. Cylindrical rod 600 is again placed onto alignment layer 300, with the adhesive surface facing alignment layer 300 still covered by a non-stick protective film. Using the at least one previously drawn alignment mark, cylindrical rod 600 is again aligned with the associated node 420.

Once aligned, an outline of cylindrical rod 600 (i.e., a circle in this embodiment) is drawn on alignment layer 300. Cylindrical rod 600 is then tilted to expose double-sided mounting tape 800. The remaining non-stick protective film is peeled away to expose the second adhesive surface, and cylindrical rod 600 is carefully lowered back into place such that rod 600 aligns with the drawn outline, ensuring that center 700 is substantially aligned with the associated node 420. This process is repeated to connect each cylindrical rod 600 to alignment layer 300.

As shown in FIG. 8, prior to slicing cylindrical rods 600, apparatus 200 includes alignment layer 300 connected to template 202 using adhesive layer 220. In addition, cylindrical rods 600 are connected to alignment layer 300 using pieces of double-sided mounting tape 800.

Referring back to FIG. 1, the cylindrical rods are sliced in step 110 to produce a plurality of rectangular seed bricks. In this embodiment, cylindrical rods 600 are sliced by a multi-wire web (not shown) that is lowered onto apparatus 200. Specifically, multi-wire web includes a plurality of vertical cutting wires that are aligned with vertical slots 206 in template 202 and a plurality of horizontal cutting wires that are aligned with horizontal slots 208 in template 202. Vertical and horizontal cutting wires may be, for example, wires impregnated with diamond dust to facilitate slicing cylindrical rods 600.

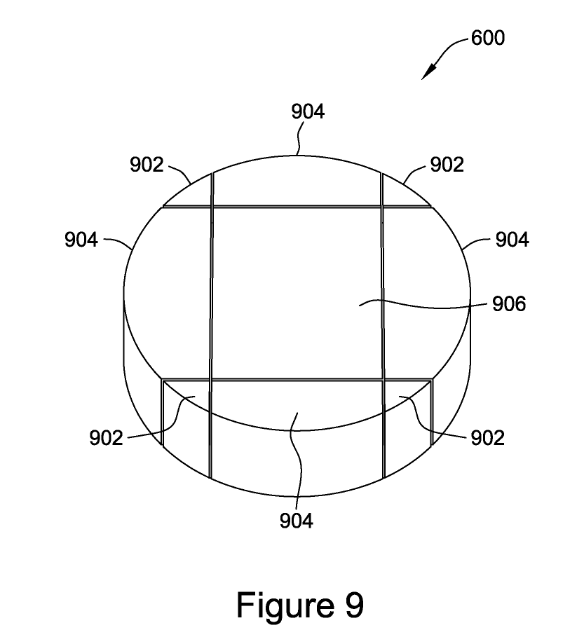

In this embodiment, multi-wire web is lowered until vertical and horizontal cutting wires cut through alignment layer 300, such that multi-wire web passes all the way through cylindrical rods 600. As multi-wire web is lowered, the vertical and horizontal cutting wires pass through and slice 110 cylindrical rods 600. FIG. 9 shows a cylindrical rod 600 after slicing 110.

As shown in FIG. 9, cylindrical rod 600 is sliced 110 into nine separate pieces: four corner portions 902, four quarter sections 904, and one rectangular seed brick 906. In this embodiment, each rectangular seed brick 906 has a cross-section of approximately 156 mm by 156 mm (roughly corresponding to dimensions of square-shaped sections 210) and a height of approximately 200 mm. In other embodiments, rectangular seed bricks 906 may have any suitable dimensions.

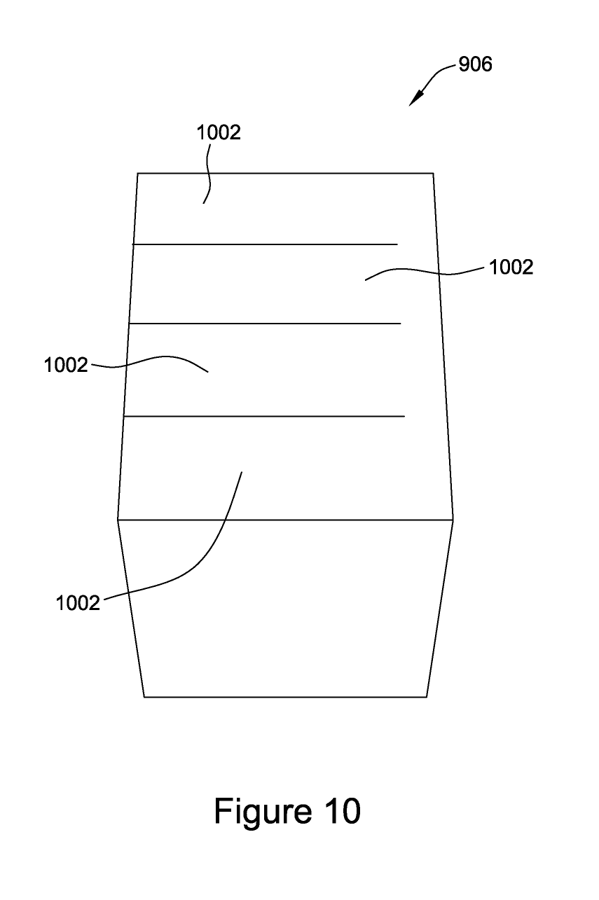

Each rectangular seed brick 906 can be marked and cropped into individual seeds 1002, as shown in FIG. 10. For example, in this embodiment, seed brick 906 is marked to be divided into four substantially identical seeds 1002.

In this embodiment, seeds 1002 are each used as a seed crystal in a directional solidification system (DSS) furnace to generate an ingot with a mono-like structure (i.e., a substantially mono-crystalline structure). Quarter sections 904 and corner portions 902 may also be cropped for use as seed crystals in a DSS furnace, as described herein. Semiconductor wafers and/or high-efficiency solar wafers may be produced from the mono-like ingot generated in the DSS furnace.

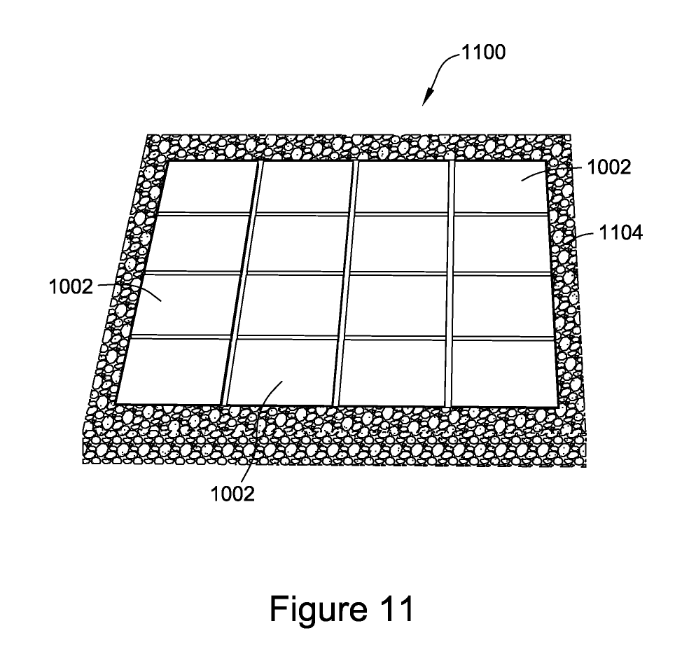

FIG. 11 shows a pre-melt arrangement 1100 including a plurality of seeds 1002 arranged in a grid. Arrangement 1100 is created in a crucible of, for example, a DSS furnace (neither shown). In arrangement 1100, seeds 1002 are surrounded by filler material 1104. In this embodiment, filler material 1104 is chipped and/or granular polysilicon. To form mono-like silicon ingots, the crucible is heated to melt seeds 1002 and filler material 1104. Seeds 1002 may also be covered with additional filler material 1104 prior to being melted.

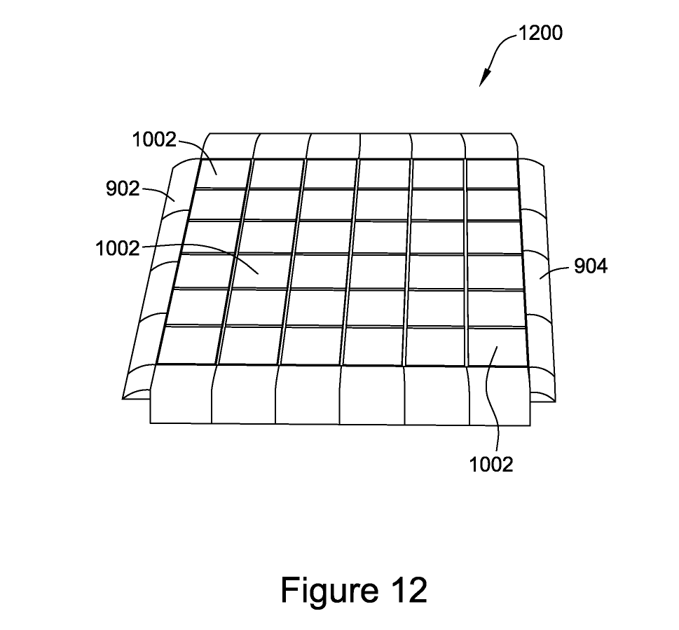

FIG. 12 shows an alternative pre-melt arrangement 1200. Similar to arrangement 1100, arrangement 1200 includes a plurality of seeds 1002 arranged in a grid in a crucible (not shown). Instead of filler material 1104 (shown in FIG. 11), seeds 1002 are surrounded by a plurality of corner portions 902 and quarter sections 904 in arrangement 1200. Entire (i.e., whole) corner portions 902 and quarter sections 904 and/or smaller cropped segments of corner portions 902 and quarter sections 904 may be used to surround seeds 1002.

Using corner portions 902 and/or quarter sections 904 in arrangement 1200 instead of filler material 1104 improves the melt when the crucible is heated. Specifically, because corner portions 902 and quarter sections 904 are monocrystalline silicon, corner portions 902 and quarter sections 904 provide more material for producing mono-like silicon ingots than the polysilicon filler material 1104 of arrangement 1100. Arrangement 1200 may also be covered with filler material 1104 prior to being melted.

Embodiments of the methods and systems described herein achieve superior results compared to prior methods and systems. For example, unlike at least some known seed brick production methods, the methods described herein produce a plurality of seed bricks significantly more quickly by simultaneously slicing a plurality of cylindrical rods. Further, unlike at least some known seed brick production methods that utilize band saws, the methods described herein utilize a multi-wire web and associated template, resulting in a uniform surface finish with parallel and square mating surfaces of the produced seed bricks, and reducing kerf loss. Moreover, the rectangular seed bricks, quarter sections, and corner portions produced using the methods described herein may be used as seeds in a crucible of a DSS furnace to produce mono-like silicon ingots. Generally, the embodiments described enable producing seed bricks easier, faster, and/or less expensively than prior systems.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A method of preparing a directional solidification system (DSS) furnace for use in semiconductor or solar manufacturing, the method comprising:
slicing a plurality of cylindrical rods to produce a plurality of rectangular seed bricks, a plurality of corner portions, and a plurality of quarter sections;
cropping the plurality of rectangular seed bricks into a plurality of rectangular seeds;
arranging the plurality of rectangular seeds in a crucible of the DSS furnace; and
surrounding the arranged seeds with at least a portion of the plurality of corner portions and the plurality of quarter sections.

2. The method of claim 1, wherein slicing a plurality of cylindrical rods comprises slicing a plurality of monocrystalline silicon rods.

3. The method of claim 1, wherein arranging the plurality of rectangular seeds in a crucible comprises arranging the plurality of rectangular seeds in a grid.

4. The method of claim 1, further comprising covering the arranged seeds with chips of polycrystalline silicon.

5. The method of claim 1, wherein slicing a plurality of cylindrical rods comprises:
connecting an alignment layer to a top surface of a template, the template including a grid of horizontal and vertical slots;
drawing a plurality of alignment lines on the alignment layer to demarcate a plurality of nodes;
connecting the plurality of cylindrical rods to the alignment layer such that a center of each rod is aligned with a corresponding node; and
slicing through the plurality of rods and the alignment layer with a wire web.

6. The method of claim 5, wherein connecting the plurality of cylindrical rods to the alignment layer comprises:
making an alignment mark on a side of at least one of the cylindrical rods; and
connecting the at least one cylindrical rod to the alignment layer such that at least one alignment mark is aligned with a diagonal alignment line of the plurality of alignment lines.

7. The method of claim 6, wherein making an alignment mark comprises making an alignment mark along a crystal 1-1-0 direction of the at least one cylindrical rod.

8. The method of claim 5, wherein drawing a plurality of alignment lines comprises:
drawing a plurality of horizontal and vertical alignment lines that align with the horizontal and vertical slots in the template; and
drawing a plurality of diagonal lines, wherein each node is an intersection of two of the plurality of diagonal lines.

9. The method of claim 5, wherein slicing through the plurality of rods comprises slicing with a wire web that includes a plurality of horizontal and vertical cutting wires that correspond to the horizontal and vertical slots in the template.

10. The method of claim 5, wherein connecting an alignment layer to a top surface of a template comprises connecting the alignment layer to the top surface of the template using a double-sided adhesive film.

11. The method of claim 5, wherein connecting a plurality of cylindrical rods to the alignment layer comprises connecting the plurality of rods to the alignment layer using a double-sided adhesive film.

12. The method of claim 1, further comprising heating the crucible to melt the arranged seeds and the at least a portion of the plurality of corner portions and the plurality of quarter sections.

13. The method of claim 1, wherein slicing a plurality of cylindrical rods comprises slicing a plurality of cylindrical rods each having a diameter greater than 220 millimeters (mm).

14. The method of claim 1, wherein slicing a plurality of cylindrical rods comprises slicing a plurality of cylindrical rods to produce a plurality of rectangular seed bricks each having a cross-section of 156 millimeters (mm) by 156 mm.

15. A method of preparing a directional solidification system (DSS) furnace for use in semiconductor or solar manufacturing, the method comprising:
slicing a plurality of cylindrical rods by connecting an alignment layer to a top surface of a template, the template including a grid of horizontal and vertical slots, and slicing through the plurality of rods and the alignment layer to produce a plurality of rectangular seed bricks, a plurality of corner portions, and a plurality of quarter sections;
cropping the plurality of rectangular seed bricks into a plurality of rectangular seeds;
arranging the plurality of rectangular seeds in a crucible of the DSS furnace; and
surrounding the arranged seeds with at least a portion of the plurality of corner portions and the plurality of quarter sections.

16. The method of claim 15, wherein slicing a plurality of cylindrical rods comprises slicing a plurality of monocrystalline silicon rods.

17. The method of claim 15, wherein arranging the plurality of rectangular seeds in a crucible comprises arranging the plurality of rectangular seeds in a grid.

18. The method of claim 15, further comprising covering the arranged seeds with chips of polycrystalline silicon.

19. The method of claim 15, further comprising heating the crucible to melt the arranged seeds and the at least a portion of the plurality of corner portions and the plurality of quarter sections.

20. The method of claim 15, wherein slicing through the plurality of rods and the alignment layer comprises slicing with a wire web that includes a plurality of horizontal and vertical cutting wires that correspond to the horizontal and vertical slots in the template.
